(19) United States
(12) Patent Application Publication
(10) Pub. No.: US 2013/0258621 A1
(43) Pub. Date: Oct. 3, 2013

(54) MICROELECTRONIC PACKAGE HAVING A COAXIAL CONNECTOR

(71) Applicants: Itsik Refaeli, Moddiin (IL); Raanan Sover, Haifa (IL); Alberto Rozic, Zoran (IL); Ran Kafri, Even Yehuda (IL); Mohamed A. Megahed, Gilbert, AZ (US)

(72) Inventors: Itsik Refaeli, Moddiin (IL); Raanan Sover, Haifa (IL); Alberto Rozic, Zoran (IL); Ran Kafri, Even Yehuda (IL); Mohamed A. Megahed, Gilbert, AZ (US)

(21) Appl. No.: 13/992,788

(22) PCT Filed: Aug. 25, 2011
(86) PCT No.: PCT/US11/49087

§ 371 Date: Jun. 10, 2013

(51) Int. Cl. B81B 7/00

(52) U.S. Cl. CPC B81B 7/007
USPC 361/760

(57) ABSTRACT

The present disclosure relates to the field of fabricating microelectronic packages and devices, wherein a microelectronic package may be formed with an interposer with at least one microelectronic component attached to an active surface of the interposer, and at least one coaxial connector attached to an opposing attachment surface of the interposer. The microelectronic package may be attached to a substrate to form the microelectronic device, wherein the substrate includes an opening therethrough for access to the at least one coaxial connector.

### BACKGROUND

Embodiments of the present description generally relate to the field of microelectronic device package designs and, more particularly, to a microelectronic device package having at least one coaxial connector.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 illustrates a top oblique plan view of an interposer, according to an embodiment of the present description.

FIG. 2 illustrates a bottom oblique plan view of the interposer of FIG. 1, according to an embodiment of the present description.

FIG. 3 illustrates a top oblique plan view of the interposer of FIG. 1 having at least one microelectronic component attached thereto, according to an embodiment of the present description.

FIG. 4 illustrates a top oblique plan view of the interposer of FIG. 3 having an encapsulant layer disposed thereon, according to an embodiment of the present description.

FIG. 5 illustrates a top oblique plan view of the interposer of FIG. 4 having a shield layer disposed thereon, according to an embodiment of the present description.

FIG. 6 illustrates a bottom oblique plan view of the structure of FIG. 5 having at least one coaxial connector disposed proximate the bottom surface of the substrate to form a microelectronic package, according to an embodiment of the present description.

FIG. 7 illustrates a bottom oblique plan view of the structure of FIG. 5 having at least one coaxial connector and at least one attachment surface contact land disposed proximate the bottom surface of the substrate to form a microelectronic package, according to an embodiment of the present description.

FIG. 8 illustrates a bottom oblique plan view of the structure of FIG. 7 having at least one attachment side microelectronic device attached to the at least one attachment surface contact land to form a microelectronic package, according to an embodiment of the present description.

FIG. 9 illustrates a side cross section view of the microelectronic package of FIG. 6 or FIG. 8 attached to a substrate, wherein the substrate includes an opening therethrough for the connection of external devices to the coaxial connector(s), according to an embodiment of the present description.

FIG. 10 illustrates a plan view of the structure of FIG. 9 along line 10-10, wherein the substrate includes an opening therethrough for the connection of external devices to the coaxial connector(s), according to an embodiment of the present description.

FIG. 11 illustrates a plan view of the microelectronic package of FIG. 6 or FIG. 8 attached to a substrate, wherein the substrate includes an opening therethrough at an edge thereof for the connection of external devices to the coaxial connector(s), according to an embodiment of the present description.

FIG. 12 illustrates an embodiment of a portable electronic device, according to embodiments of the present description.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present invention. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

Embodiments of the present description relate to the field of fabricating microelectronic packages and microelectronic devices, wherein the microelectronic package may be formed with an interposer with at least one microelectronic component attached to an active surface of the interposer, and at least one coaxial connector attached to an opposing attachment surface of the interposer. The microelectronic packages may be attached to a substrate, wherein the substrate includes an opening therethrough for access to the at least one coaxial connector to form the microelectronic device. As will be understood to those skilled in the art, the coaxial connector may be used to connect coaxial cables for use as a transmission lines for radio frequency signals, in applications such as feedlines connecting radio transmitters and receivers with their antennas, computer network connections, and distributing cable television signals.

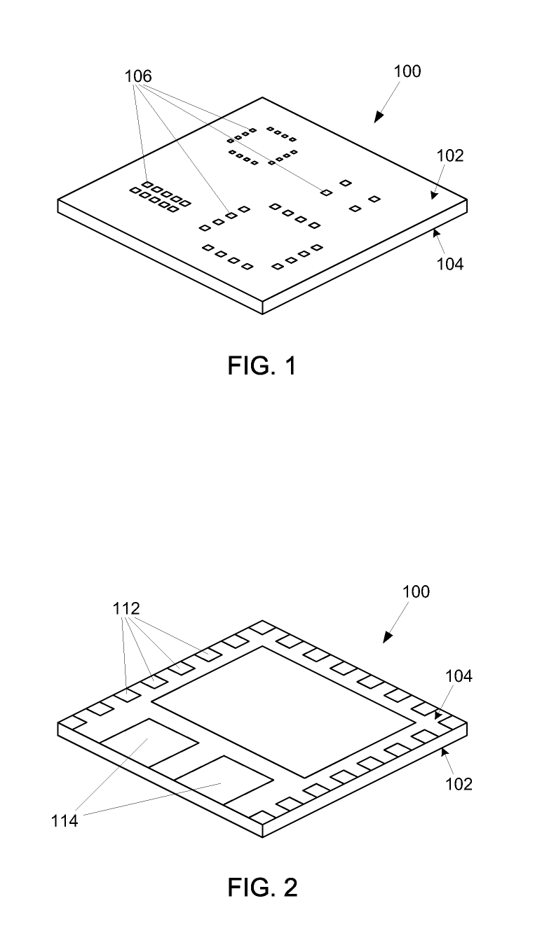

FIG. 1 illustrates a top oblique plan view of an interposer 100 having an active surface 102 and an opposing attachment surface 104. The interposer active surface 102 may include a plurality of contact lands 106 for the attachment of at least one microelectronic component (not shown), as will be discussed. As shown in FIG. 2, the interposer attachment surface 104 may include at least one attachment land 112 disposed thereon and/or therein, and at least one coaxial connection land 114.

It is understood that the interposer 100 may be comprised of a plurality dielectric material layers having a plurality of conductive traces formed thereon with conductive vias extending through the dielectric material layers to form signal routes to connect the interposer active surface contact lands 106, the interposer attachment surface attachment lands 112, and/or the coaxial connection lands 114. The specific elements of the interposer 100, i.e. the dielectric layers and conductive traces, are not shown in the figures, as such structures are well known in the art. Furthermore, the coaxial connection land(s) 114 are merely illustrated schematically, as the specific structures and connection within the coaxial connection land(s) 114 are well known in the art.

The dielectric layers may be any appropriate material or materials, including but not limited to, bismaleimine triazine resin, fire retardant grade 4 material, polyimide material, glass reinforced epoxy matrix material, and the like, as well as laminates or multiple layers thereof. The conductive traces (not shown), the interposer active surface contact lands 106, the interposer attachment surface attachment lands 112, and/or the coaxial connection lands 114 may be any appropriate conductive material or materials, including but not limited to, copper, aluminum, silver, gold, and alloys thereof, and may be made by any technique known in the art, including but not limited to photolithography and plating. The conductive vias (not shown) may be any appropriate conductive material including but not limited to copper, aluminum, silver, gold, and alloys thereof, and may be made by any technique known in the art, including but not limited to laser drilling, ion drilling, photolithography, plating, and deposition.

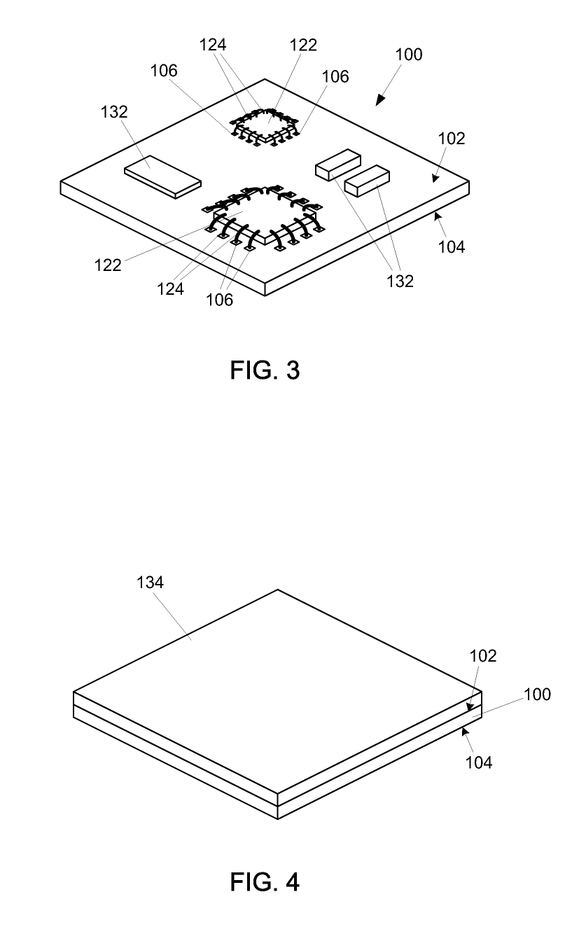

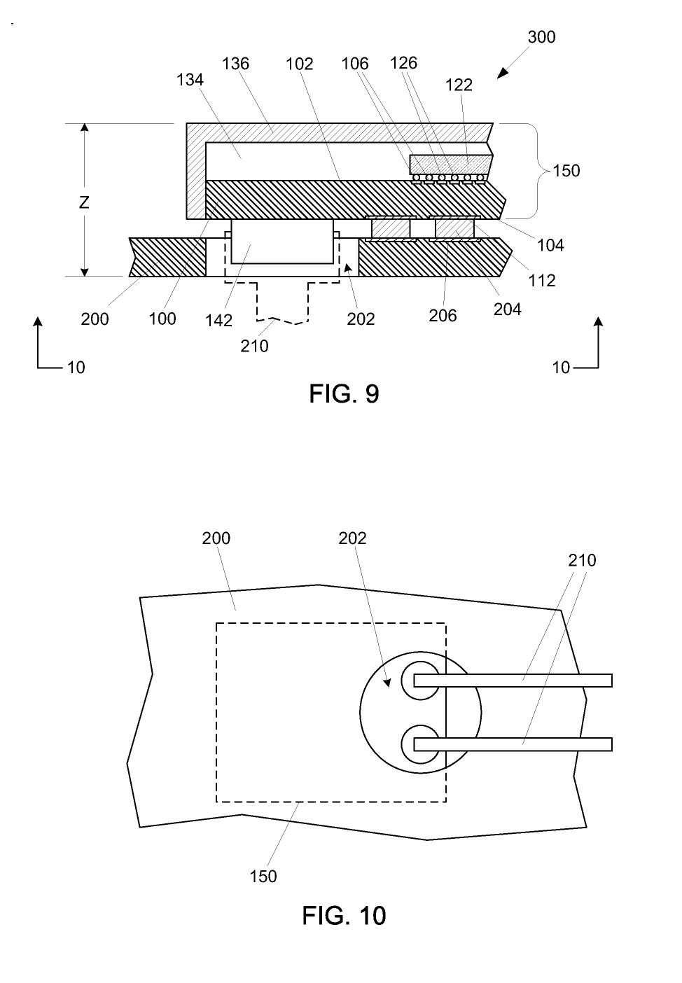

As shown in FIG. 3, at least one microelectronic component (shown as elements 122 and 132) may be attached to the interposer active surface 102. The microelectronic components 122 and 132 may be any desired devices, including but not limited to passive devices (resistors, capacitors, inductors, and the like), microprocessors (single or multi-core), memory devices, chipsets, graphics devices, application specific integrated circuits, or the like. As illustrated, the microelectronic components 122 may be attached with a wire bond arrangement, wherein the microelectronic components 122 are mounted to the interposer active surface 102 and connected to respective interposer active surface contact lands 106 with at least one bond wire 124. As also illustrated, the microelectronic components 132 may be surface mounted to the interposer active surface contact lands 106 with solder interconnects 126 (shown in FIG. 9) in a flip-chip configuration and/or with leads 126 (not shown) in a surface mount configuration, as will be understood to those skilled in the art.

As shown in FIG. 4, after the microelectronic components (see elements 122 and 132 of FIG. 3) are attached to the interposer active surface 102, an encapsulation material 134 may be disposed over the interposer active surface 102 and over the microelectronic components 122 and 132 to prevent physical and/or chemical damage. The encapsulation material 134 may be any appropriate encapsulation material including but not limited to a filled epoxy resin or the like.

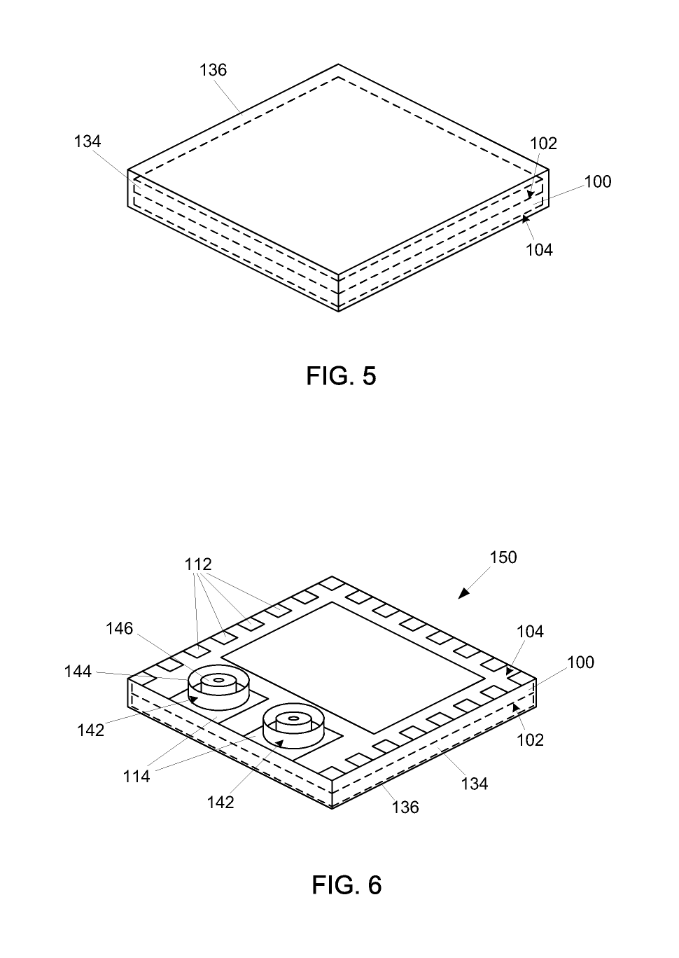

As shown in FIG. 5, a shielding layer 136 may be formed or layered on the encapsulation material 134 and on side of the interposer 100. The shielding layer 136 may prevent electronic interference, as will be understood to those skilled in the art.

As shown in FIG. 6, at least one coaxial connector 142 may be attached to a respective coaxial connection land 114 proximate the interposer attachment surface 104 (shown in FIG. 6 as a pair of coaxial connectors 142 and a corresponding pair of coaxial connection lands 114) to form a microelectronic package 150. The specific structures and elements of the coaxial connectors 142 and the coaxial connection lands 114 are not shown in the figures, as such structures are well known in the art. It is understood that the coaxial connectors 142 may be any known coaxial connectors, including but not limited to, RCA-type, C-type, F-type, N-type, WFL, UFL, Bayonet Neil-Concelman (BNC), Threaded Neil-Concelman (TNC), Subminiature A (SMA), Amphenol Precision Connector (APC), and the like.

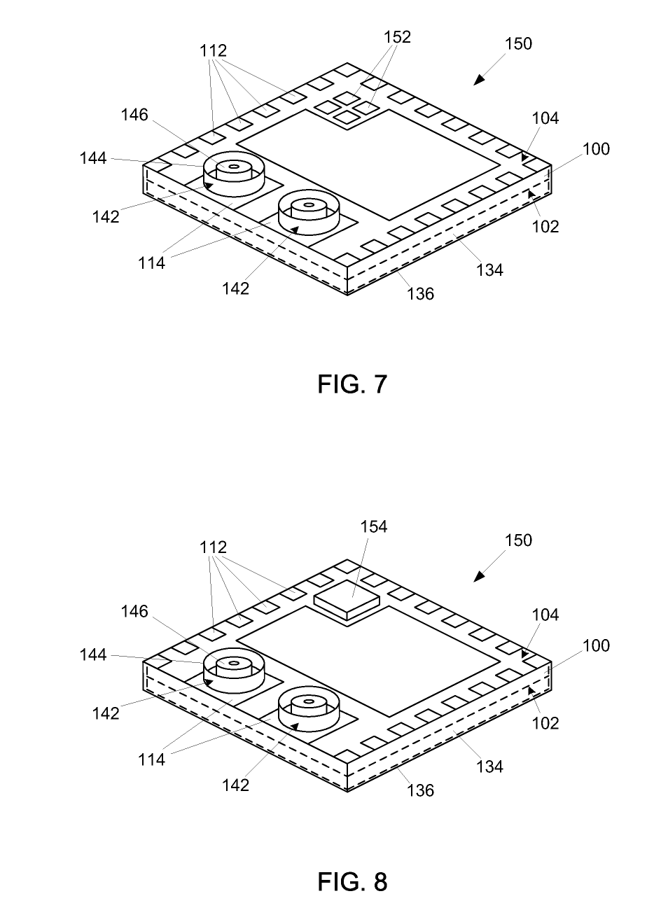

In another embodiment, attachment surface contact lands 152 may be formed proximate the attachment surface 104, as shown in FIG. 7. At least one attachment side microelectronic component 154 may be attached to the at least one attachment surface contact land 152 (see FIG. 7), as shown in FIG. 8. The attachment side microelectronic component 154 may include any appropriate microelectronic device including but not limited to crystal oscillators, such as XTAL and TCXO devices.

FIG. 9 illustrates a side cross section view of the microelectronic package 150 of FIG. 6 or FIG. 8 attached to a substrate 200 to form a microelectronic device 300, wherein the substrate 200 includes at least one opening 202 therethrough for the connection of external devices (not shown) through at least one coaxial cable 210 (shown in dashed lines) to at least one coaxial connector 142. The substrate 200 may be a motherboard or other such support/communication substrate, as will be understood to those skilled in the art.

As with the interposer 100, the substrate 200 may be comprised of a plurality dielectric material layers having a plurality of conductive traces formed thereon with conductive vias extending through the dielectric material layers to form signal routes to connect the substrate lands 106 with external device(s) (not shown). The dielectric layers, the conductive traces, and the conductive vias may be made of any appropriate materials and by any appropriate techniques known in the art, such as those discussed with regard to the interposer 100.

Referring back to FIG. 9, the substrate 200 may have at least one substrate contact land 206, wherein at least one interconnector 204 may extend between the interposer attachment surface attachment lands 112 and their respective substrate contact lands 206 to form the microelectronic device 300. The interconnectors 204 may be any appropriate material including but not limited to solder materials, such as lead/tin alloys (for example 63% tin/37% lead solder), or lead-free solders (for example, tin, tin/bismuth, eutectic tin/silver, ternary tin/silver/copper, eutectic tin/copper, indium, and indium based alloys).

By locating the coaxial connectors 142 on the attachment surface 104 of the interposer 100, the microelectronic device 300 may have a Z-height (illustrated in FIG. 6 as element Z) lower than devices having coaxial connectors on the active surface 102 of the interposer 100 (not shown). This lower Z-height may be advantageous of use in hand-held product applications where the thickness of the overall product may be a consideration. Further, the location of the coaxial connectors 142 on the attachment surface 104 of the interposer 100 may result in a reduction of the size of the microelectronic package 150 which may reduce the size of hand-held product or other such products.

Furthermore, the location of the coaxial connectors 142 on the attachment surface 104 of the interposer 100 may result in a microelectronic package 150 that may be capable of being regulated/certified at a package level rather than after the final product is assembled, as will be understood to those skilled in the art. Moreover, the location of the coaxial connectors 142 on the attachment surface 104 of the interposer 100 may reduce the cost of the microelectronic package 150, as the placing coaxial connectors on the active surface 102 of the interposer 100 (not shown) as known in the art, may require different shielding type (metal-cap) which may then requires all microelectronic components 122 and 132 to be self-packaged with individual shielding (not shown).

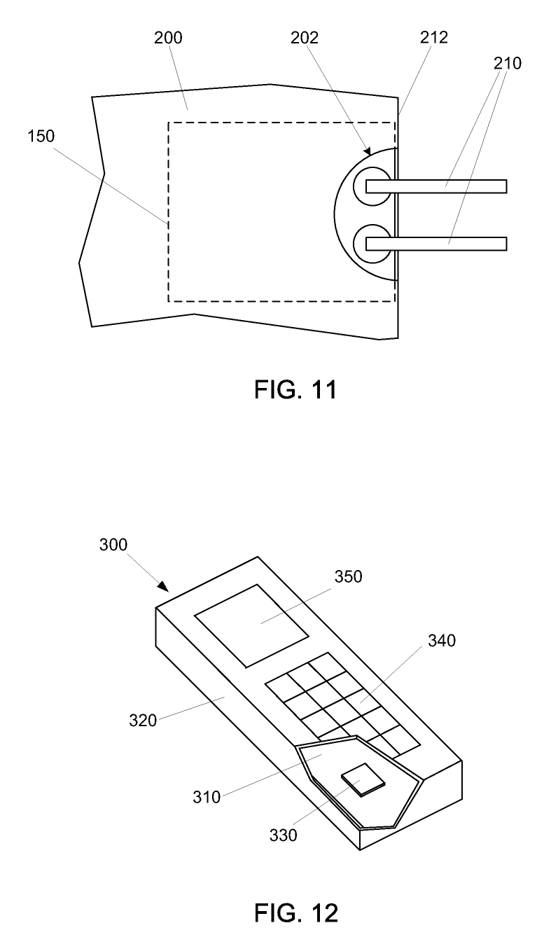

As show in FIG. 9 and also in FIG. 10, which is a plan view along line 10-10 of FIG. 9, the opening 202 may extend through the substrate 200 within a periphery (not shown) thereof. However, it is understood that the opening 202 may extend through the substrate 200 at an edge 212 thereof, as shown in FIG. 11.

FIG. 12 illustrates an embodiment of a portable system/device 300, such as a portable computer, a mobile telephone, a digital camera, a digital music player, a web tablet/pad device, a personal digital assistant, a pager, an instant messaging device, or other devices. The portable system/device 300 may be adapted to transmit and/or receive information wirelessly, such as through a wireless local area network (WLAN) system, a wireless personal area network (WPAN) system, and/or a cellular network. The portable system/device 300 may comprise a substrate 310 within a housing 320. The substrate 310 may have various microelectronic packages 330 (such as microelectronic package 150 previously discussed). The substrate 310 may be attached to various peripheral devices including an input device 340, such as keypad, and a display device 350, such an LCD display. It is understood that the display device 350 may also function as the input device, if the display device 350 is touch sensitive. The embodiments of the present description may be incorporated into the microelectronic package 330, wherein coaxial connectors (see FIG. 5) are including in the microelectronic package 330 and wherein an opening is formed in the substrate 310 to access the coaxial connector(s) therethrough (see FIG. 6).

It is understood that the subject matter of the present description is not necessarily limited to specific applications illustrated in FIGS. 1-7. Further, other devices and interconnections, as known in the art, may be combined with the subject matter of the present description. Still further, although the microelectronic substrates of the present description are described in reference to a few microelectronic applications, it is understood that the concepts may be applied to a variety of applications, including but not limited, to test fixtures, mobile devices, desktop and server systems with central processing units and/or graphics processing units, high-definition multimedia interface motherboards, and the like. Furthermore, although the microelectronic substrates of the present description are described with examples specifically in the field of microelectronic packaging, it will be understood by those skilled in the art that the concepts disclosed in the present description may be applied to a variety of electronic and microelectronic applications.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. A microelectronic package comprising:
an interposer having an active surface and an attachment surface;
at least one contact land on the interposer active surface, configured to couple to at least microelectronic component on the interposer active surface; and
at least one coaxial connection land on the interposer attachment surface, configured to coupled to at least one coaxial connector.

2. The microelectronic package of claim 1, further including at least one microelectronic component coupled to at least one interposer active surface contact land.

3. The microelectronic package of claim 2, the at least one microelectronic component is attached to at least one contact with at least one bond wire.

4. The microelectronic package of claim 2, the at least one microelectronic component is attached to at least one contact with at least one solder interconnect.

5. The microelectronic package of claim 1, further including at least one coaxial connector coupled to at least one interposer attachment surface coaxial connection land.

6. The microelectronic package of claim 2, further including an encapsulation material disposed over the interposer active surface and the at least one microelectronic component.

7. The microelectronic package of claim 6, further including a shielding layer disposed on the encapsulation material.

8. The microelectronic package of claim 1, further including at least one attachment land disposed proximate the interposer attachment surface.

9. The microelectronic package of claim 1, further including at least one contact land disposed proximate the interposer attachment surface.

10. The microelectronic package of claim 9, further including at least one microelectronic component attached to the at least one interposer attachment surface contact land.

11. A microelectronic device comprising:
a microelectronic package, including:
an interposer having an active surface and an attachment surface;
at least one contact land on the interposer active surface, configured to couple to at least microelectronic component on the interposer active surface; and
at least one coaxial connection land on the interposer attachment surface, configured to coupled to at least one coaxial connector; and
a substrate having an opening extending therethrough, wherein the microelectronic package is attached to the substrate such that the coaxial connector is accessible through the substrate opening.

12. The microelectronic device of claim 11, further including at least one microelectronic component coupled to at least one interposer active surface contact land.

13. The microelectronic device of claim 11, further including at least one coaxial connector coupled to at least one interposer attachment surface coaxial connection land.

14. The microelectronic device of claim 12, further including an encapsulation material disposed over the interposer active surface and the at least one microelectronic component.

15. The microelectronic device of claim 14, further including a shielding layer disposed on the encapsulation material.

16. The microelectronic device of claim 11, further including at least one attachment land disposed proximate the interposer attachment surface.

17. The microelectronic device of claim 11, further including at least one contact land disposed proximate the interposer attachment surface.

18. The microelectronic device of claim 17, further including at least one microelectronic component attached to the at least one interposer attachment surface contact land.

19. The microelectronic device of claim 11, wherein the microelectronic package is attached to the substrate through at least one interconnector extending between at least one attachment land and a respective at least one substrate contact land.

20. The microelectronic device of claim 19, wherein the interconnector comprises a solder material.

21. The microelectronic device of claim 11, wherein the substrate opening is positioned at an edge of the substrate.

22. A system; comprising:
a housing;
a microelectronic device disposed within the housing, wherein the microelectronic device, comprises:
a microelectronic package, including:
an interposer having an active surface and an attachment surface;
at least one contact land on the interposer active surface, configured to couple to at least microelectronic component on the interposer active surface; and
at least one coaxial connection land on the interposer attachment surface, configured to coupled to at least one coaxial connector; and
a substrate having at least one opening extending therethrough, wherein the microelectronic package it attached to the substrate such that at least one coaxial connector is accessible through at least one substrate opening; and
a coaxial cable extending through the at least one substrate opening and attached to the at least one coaxial connector.

23. The system of claim 22, further including at least one microelectronic component coupled to at least one interposer active surface contact land.

24. The system of claim 22, further including at least one coaxial connector coupled to at least one interposer attachment surface coaxial connection land.

25. The system of claim 23, wherein the microelectronic package further includes an encapsulation material disposed over the interposer active surface and the at least one microelectronic component.

26. The system of claim 25, wherein the microelectronic package further includes a shielding layer disposed on the encapsulation material.

27. The system of claim 22, wherein the microelectronic package is attached to the substrate through at least one interconnector extending between at least one attachment land and a respective at least one substrate contact land.

28. The system of claim 27, wherein the interconnector comprises a solder material.

29. The system of claim 22, wherein the substrate opening is positioned at an edge of the substrate.

30. The system of claim 22, further including at least one contact land disposed proximate the interposer attachment surface and at least one microelectronic component attached to at least one attachment surface contact land.
